(19) United States
(12) Patent Application Publication
(10) Pub. No.: US 2026/0082718 A1
(43) Pub. Date: Mar. 19, 2026

(54) LIGHT DETECTION ELEMENT AND ELECTRONIC APPARATUS

(71) Applicant: SONY SEMICONDUCTOR SOLUTIONS CORPORATION, Kanagawa (JP)

(72) Inventor: Hiroyuki MORI, Kanagawa (JP)

(73) Assignee: SONY SEMICONDUCTOR SOLUTIONS CORPORATION, Kanagawa (JP)

(21) Appl. No.: 19/105,931

(22) PCT Filed: Aug. 30, 2023
(86) PCT No.: PCT/JP2023/031513

§ 371 Date: Feb. 24, 2025

(30) Foreign Application Priority Data
Sep. 8, 2022 (JP) 2022-142968

(51) Int. Cl. H10F 39/00; H01L 23/522; H04N 25/59; H04N 25/771; H04N 25/772; H04N 25/79; H10F 39/18

(52) U.S. Cl. CPC H10F 39/811; H04N 25/771; H04N 25/772; H10F 39/18; H10F 39/807; H10W 20/496; H04N 25/59; H04N 25/79

(57) ABSTRACT

A light detection element including: a photoelectric conversion section that is in a semiconductor substrate and generates a charge corresponding to incident light; a first accumulation section that accumulates the generate charge; an amplification transistor that generates an input signal corresponding to an amount of the accumulated charge; a second accumulation section to which a saturated charge is transferred from the photoelectric conversion section via the first accumulation section; a conversion efficiency switching transistor that transfers the saturated charge to the second accumulation section to switch a conversion efficiency; a reset transistor that resets the charge accumulated in the first accumulation section and the saturated charge accumulated in the second accumulation section; and a differential input circuit that compares the input signal generated by the amplification transistor with a reference signal and outputs a comparison result, in which the second accumulation section includes a MIM capacitor having a three-dimensional structure.

### FIELD

The present disclosure relates to a light detection element and an electronic apparatus.

### BACKGROUND

In recent years, there has been proposed an imaging device in which an analog/digital converter (ADC) that converts an analog signal from a photodiode into a digital signal is provided for each pixel (light detection element). For example, one example of such an imaging device can be an imaging device described in Patent Literature 1 or Patent Literature 2 below.

### CITATION LIST

### Patent Literature

Patent Literature 1: WO 2016/136448 A
Patent Literature 2: WO 2018/018215 A

### SUMMARY

### Technical Problem

In the above-described imaging device (light detection device) in which the ADC is provided for each pixel (light detection element), there is a problem that the saturation signal amount of the pixel is reduced as compared with the conventional configuration. If the saturation signal amount of the pixel is low, it is difficult to realize a high dynamic range of the imaging device.

The present disclosure has been made in view of such a situation, and proposes a light detection element and an electronic apparatus capable of increasing the saturation signal amount in the configuration in which the ADC is provided for each pixel.

### Solution to Problem

According to the present disclosure, there is provided a light detection element including: a photoelectric conversion section that is provided in a semiconductor substrate and generates a charge corresponding to incident light; a first accumulation section that accumulates the charge generated by the photoelectric conversion section; an amplification transistor that generates an input signal corresponding to an amount of the charges accumulated in the first accumulation section; a second accumulation section to which a saturated charge is transferred from the photoelectric conversion section via the first accumulation section; a conversion efficiency switching transistor that transfers the saturated charge to the second accumulation section to switch a conversion efficiency; a reset transistor that resets the charge accumulated in the first accumulation section and the saturated charge accumulated in the second accumulation section; and a differential input circuit that compares the input signal generated by the amplification transistor with a reference signal and outputs a comparison result. In the light detection element, the second accumulation section includes a metal insulator metal (MIM) capacitor having a three-dimensional structure or a metal oxide semiconductor (MOS) capacitor.

Furthermore, according to the present disclosure, there is provided an electronic apparatus on which a light detection device including a light detection element is mounted. In the light detection device, the light detection element includes: a photoelectric conversion section that is provided in a semiconductor substrate and generates a charge corresponding to incident light; a first accumulation section that accumulates the charge generated by the photoelectric conversion section; an amplification transistor that generates an input signal corresponding to an amount of the charges accumulated in the first accumulation section; a second accumulation section to which a saturated charge is transferred from the photoelectric conversion section via the first accumulation section; a conversion efficiency switching transistor that transfers the saturated charge to the second accumulation section to switch a conversion efficiency; a reset transistor that resets the charge accumulated in the first accumulation section and the saturated charge accumulated in the second accumulation section; and a differential input circuit that compares the input signal generated by the amplification transistor with a reference signal and outputs a comparison result, and the second accumulation section includes a metal insulator metal (MIM) capacitor having a three-dimensional structure or a metal oxide semiconductor (MOS) capacitor.

### BRIEF DESCRIPTION OF DRAWINGS

FIG. 1 is a diagram illustrating a schematic configuration of an imaging device according to the present disclosure.

FIG. 2 is a block diagram illustrating a configuration example of a pixel according to the present disclosure.

FIG. 3 is a circuit diagram illustrating a circuit configuration example of the pixel according to the present disclosure.

FIG. 4 is a circuit diagram illustrating a circuit configuration example of a pixel according to Comparative Example 2.

FIG. 5 is an explanatory diagram for describing a background of an embodiment of the present disclosure.

FIG. 6 is a diagram illustrating a cross-sectional configuration example of a pixel according to a first embodiment of the present disclosure.

FIG. 7 is a partially enlarged view of FIG. 6.

FIG. 8 is a diagram illustrating a cross-sectional configuration example of a pixel according to a second embodiment of the present disclosure.

FIG. 9 is a diagram illustrating a cross-sectional configuration example of a pixel according to a third embodiment of the present disclosure.

FIG. 10 is a circuit diagram illustrating a circuit configuration example of a pixel according to a fourth embodiment of the present disclosure.

FIG. 11 is a diagram illustrating a cross-sectional configuration example of the pixel according to the fourth embodiment of the present disclosure.

FIG. 12 is an explanatory diagram (part 1) for explaining a positional relationship between a wiring network and a pad according to a fifth embodiment of the present disclosure.

FIG. 13 is an explanatory diagram (part 2) for explaining the positional relationship between the wiring network and the pad according to the fifth embodiment of the present disclosure.

FIG. 14 is an explanatory diagram (part 1) for explaining an example of a wiring network according to the fifth embodiment of the present disclosure.

FIG. 15 is an explanatory diagram (part 2) for explaining the example of the wiring network according to the fifth embodiment of the present disclosure.

FIG. 16 is an explanatory diagram (part 3) for explaining the positional relationship between the wiring network and the pad according to the fifth embodiment of the present disclosure.

FIG. 17 is an explanatory diagram (part 4) for explaining the positional relationship between the wiring network and the pad according to the fifth embodiment of the present disclosure.

FIG. 18 is an explanatory diagram (part 5) for explaining the positional relationship between the wiring network and the pad according to the fifth embodiment of the present disclosure.

FIG. 19 is an explanatory diagram (part 6) for explaining the positional relationship between the wiring network and the pad according to the fifth embodiment of the present disclosure.

FIG. 20 is an explanatory diagram illustrating an example of a schematic functional configuration of a camera.

FIG. 21 is a block diagram illustrating an example of a schematic functional configuration of a smartphone.

FIG. 22 is a block diagram depicting an example of schematic configuration of a vehicle control system.

FIG. 23 is a diagram of assistance in explaining an example of installation positions of an outside-vehicle information detecting section and an imaging section.

### DESCRIPTION OF EMBODIMENTS

Hereinafter, preferred embodiments of the present disclosure will be described in detail with reference to the accompanying drawings. Note that, in the present description and the drawings, components having substantially the same functional configuration are denoted by the same reference numerals, and redundant description is omitted. In addition, in the present description and the drawings, a plurality of components having substantially the same or similar functional configuration may be distinguished by attaching different alphabets after the same reference numeral. However, in a case where it is not particularly necessary to distinguish between the plurality of components having substantially the same or similar functional configuration, only the same reference numeral is attached.

In addition, the drawings referred to in the following description are drawings for promoting the description of the embodiments of the present disclosure and the understanding thereof, and shapes, dimensions, ratios, and the like illustrated in the drawings may be different from actual ones for the sake of clarity. Furthermore, components and the like included in the elements and devices illustrated in the drawings can be appropriately modified in design in consideration of the following description and known techniques.

In addition, in the following description, a case where the embodiment of the present disclosure is applied to a back-illuminated imaging device will be described as an example, and therefore, light is incident from a back surface side of the substrate in the imaging device. Furthermore, in the description using a cross-sectional view of the imaging device, the vertical direction of the stacked structure of the imaging device corresponds to a relative direction in a case where the light receiving surface where incident light enters the imaging device is on the lower side, and may be different from the vertical direction according to the actual gravitational acceleration.

In addition, the statements of specific shapes in the following description do not mean only geometrically defined shapes. Specifically, the statements of specific shapes in the following description include a case where there is an allowable difference (error/distortion) in elements, manufacturing processes thereof, and uses/operations thereof, and shapes similar to the stated shapes. For example, in the following description, the expression “substantially rectangular wave shape” means not only a rectangular wave but also a shape similar to the rectangular wave.

Furthermore, in the following description of circuits (electrical connections), “electrically connected” means that a plurality of elements are connected such that electricity (signal) passes therebetween, unless otherwise specified. In addition, “electrically connected” in the following description includes not only a case of directly and electrically connecting the plurality of elements but also a case of indirectly and electrically connecting the plurality of elements via other elements.

Note that the description will be given in the following order.
1. Background to creating the embodiments of the present disclosure
   1.1 Schematic configuration example of the imaging device
   1.2 Block configuration example of the pixel
   1.3 Circuit configuration example of the pixel
   1.4 Background
2. First embodiment
3. Second embodiment
4. Third embodiment
5. Fourth embodiment
6. Fifth embodiment
7. Summary
8. Application example
   8.1 Application example to a camera
   8.2 Application example to a smartphone
   8.3 Application example to a mobile body
9. Supplement

### 1. Background to Creating the Embodiments of the Present Disclosure

### <1.1 Schematic Configuration Example of the Imaging Device>

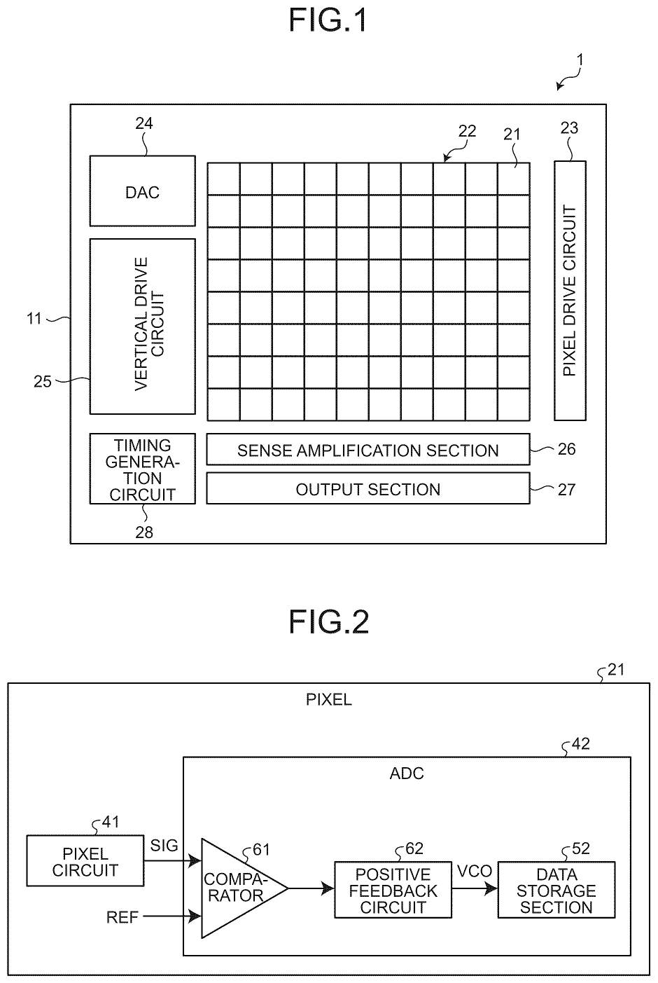

A background to the creation of the embodiments of the present disclosure by the present inventor will be described. First, a schematic configuration of an imaging device (light detection device) 1 according to the present disclosure will be described with reference to FIG. 1. FIG. 1 is a diagram illustrating the schematic configuration example of the imaging device 1 according to the present disclosure.

As illustrated in FIG. 1, the imaging device 1 includes a pixel array section 22 in which pixels (light detection elements) 21 are arrayed in a matrix on a semiconductor substrate 11 using, for example, silicon (Si). Then, a pixel drive circuit 23, a digital/analog converter (DAC) 24, a vertical drive circuit 25, a sense amplification section 26, an output section 27, and a timing generation circuit 28 are formed around the pixel array section 22 on the semiconductor substrate 11. Hereinafter, an outline of each component of the imaging device 1 will be sequentially described.

### (Pixel 21)

The pixel 21 mainly includes a pixel circuit and an ADC as described later. The pixel circuit can generate charges corresponding to light incident on the imaging device 1 and output an analog pixel signal corresponding to the amount of charges to the ADC. Furthermore, the ADC can convert the analog pixel signal supplied from the pixel circuit into a digital signal. Note that a detailed configuration of the pixel 21 will be described later.

### (Pixel Drive Circuit 23)

The pixel drive circuit 23 can drive the pixel circuit in the pixel 21 and a comparator included in the ADC.

### (DAC 24)

The DAC 24 can generate a reference signal that is a slope signal whose level (voltage) monotonously decreases with the lapse of time, and output the reference signal to the comparator included in the ADC of each pixel 21.

### (Vertical Drive Circuit 25)

The vertical drive circuit 25 can output the digital pixel signal generated in the pixel 21 to the sense amplification section 26 in a predetermined order based on a timing signal supplied from the timing generation circuit 28 to be described later.

### (Sense Amplification Section 26)

The sense amplification section 26 can amplify the digital pixel signal output from the pixel 21 and output the amplified signal to the output section 27 to be described later.

### (Output Section 27)

The output section 27 can perform predetermined digital signal processing as necessary, such as black level correction processing of correcting a black level or correlated double sampling (CDS), on the pixel signal amplified by the sense amplification section 26, and output the processed signal to the outside.

### (Timing Generation Circuit 28)

The timing generation circuit 28 includes a timing generator that generates various timing signals and the like, and can supply the generated various timing signals to the pixel drive circuit 23, the DAC 24, the vertical drive circuit 25, and the like.

Note that the configuration of the imaging device 1 according to the present disclosure is not limited to the configuration illustrated in FIG. 1, and may be configured in combination with other components or the like according to the application or the like of the imaging device 1, for example. In addition, although it has been described that all the components constituting the imaging device 1 are formed on one semiconductor substrate 11 in FIG. 1, the present disclosure is not limited to this configuration. For example, the imaging device 1 of the present disclosure may be constituted by each component provided on a plurality of different semiconductor substrates.

### <1.2 Block Configuration Example of the Pixel>

Next, a block configuration example of the pixel 21 according to the present disclosure will be described with reference to FIG. 2. FIG. 2 is a block diagram illustrating a configuration example of the pixel 21 according to the present disclosure. As illustrated in FIG. 2, the pixel 21 mainly includes a pixel circuit 41 and an ADC 42. That is, in the present disclosure, the ADC 42 is provided for each pixel 21 in the imaging device 1. Hereinafter, an outline of each component of the pixel 21 will be sequentially described.

### (Pixel Circuit 41)

The pixel circuit 41 includes a photoelectric conversion section (photo diode) that generates charges corresponding to light incident on the imaging device 1, and can output an analog pixel signal SIG corresponding to the amount of charges generated by the photoelectric conversion section to the ADC 42. Specifically, in addition to the photoelectric conversion section, the pixel circuit 41 includes a transfer transistor that transfers the charges, an accumulation section that accumulates the charges, an amplification transistor that converts charges accumulated in the accumulation section into a voltage, and the like. Note that a detailed configuration of the pixel circuit 41 will be described later.

### (ADC 42)

As described above, the ADC 42 can convert the analog pixel signal SIG supplied from the pixel circuit 41 into the digital signal. As illustrated in FIG. 2, the ADC 42 mainly includes a comparator (differential input circuit) 61, a positive feedback circuit (PFB) 62, and a data storage section (storage section) 52.

The comparator 61 has a pair of input terminals, and the analog pixel signal SIG (input signal) output from the pixel circuit 41 is input to one input terminal, while a reference signal REF output from the DAC 24 is input to the other input terminal. Then, the comparator 61 compares the analog pixel signal SIG with the reference signal REF, and inverts an output signal VCO as a comparison result signal indicating a comparison result when the pixel signal SIG and the reference signal REF become at the same level.

The positive feedback circuit 62 includes, for example, a positive feedback circuit that feeds back a part of the output and adds the feedback to the input. The positive feedback circuit 62 can speed up a response to the output signal VCO output from the comparator 61.

The output signal VCO from the comparator 61 is input to the data storage section 52. Furthermore, signals related to writing and reading of the pixel signals and the like may be input to the data storage section 52 from the vertical drive circuit 25 and the like.

Note that the configuration of the pixel 21 according to the present disclosure is not limited to the configuration illustrated in FIG. 2, and, for example, may be configured in combination with other components or the like according to the application or the like of the imaging device 1.

### <1.3 Circuit Configuration Example of the Pixel>

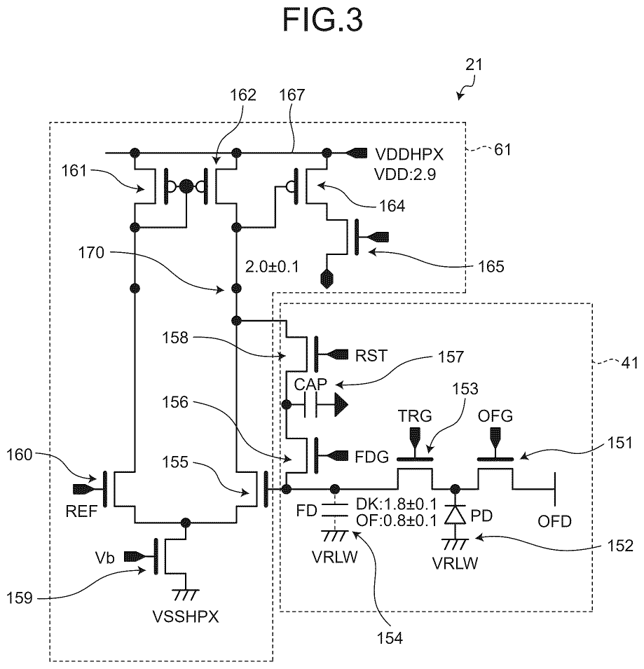

Next, a circuit configuration example of the pixel 21 according to the present disclosure will be described with reference to FIG. 3. FIG. 3 is a circuit diagram illustrating a circuit configuration example of the pixel 21 according to the present disclosure. Note that FIG. 3 illustrates only a circuit of a main part of the pixel 21.

First, as illustrated in FIG. 3, the pixel 21 includes, as the pixel circuit 41, a discharge transistor (OFG) 151, a photo diode (PD) (photoelectric conversion section) 152, a transfer transistor (TRG) 153, a floating diffusion (FD) section (first accumulation section) 154, an amplification transistor 155, a conversion efficiency switching transistor (FDG) 156, a capacitor (second accumulation section) 157, and a reset transistor (RST) 158. Note that the various transistors described above are referred to as pixel transistors, and constituted by, for example, complementary metal oxide semiconductor (CMOS) transistors.

Specifically, the PD 152 can generate and accumulate charges corresponding to the amount of incident light. A cathode of the PD 152 is electrically connected to a terminal (source or drain) of the discharge transistor 151, and an anode of the PD 152 is electrically connected to a reference potential line (for example, ground). In addition, the discharge transistor 151 can discharge the charges accumulated in the PD 152 to a power supply line or the like in an ON state.

One terminal (source or drain) of the transfer transistor 153 is connected to the cathode of the PD 152, the other terminal is connected to the FD section 154, and the transfer transistor 153 can transfer the charges from the PD 152 to the FD section 154.

The FD section 154 can accumulate the charges from the PD 152, and can convert the accumulated charges into a voltage corresponding to the amount thereof in cooperation with the amplification transistor 155. A gate terminal of the amplification transistor 155 is connected to the FD section 154, and the signal (input signal) SIG corresponding to the amount of charges accumulated in the FD section 154 is input to the amplification transistor 155.

One terminal of the conversion efficiency switching transistor 156 (source or drain) is connected to the FD section 154, and the other terminal is connected to the capacitor 157 and the reset transistor 158. The conversion efficiency switching transistor 156 can connect the capacitor 157 to the FD section 154 and reset the charges accumulated in the FD section 154 and/or the capacitor 157 in cooperation with the reset transistor 158. In addition, one terminal of the capacitor 157 is connected to the conversion efficiency switching transistor 156, and the other terminal is connected to a ground, for example.

Specifically, the conversion efficiency switching transistor 156 is used to switch the conversion efficiency of the pixel 21. In general, the amount of charges generated by the PD 152 increases at the time of photographing in a bright place (high illuminance), and the charges exceeding the saturation signal amount overflows from the PD 152. Thus, in the pixel 21, the conversion efficiency switching transistor 156 is turned on at the time of high illuminance, and the overflowing charges (saturated charges) is transferred to the capacitor 157 through the FD section 154. As a result, the conversion efficiency decreases at the time of high illuminance so that the voltage V does not become too large when the amount of charges is converted into the voltage by the amplification transistor 155 according to Q (charge amount)=C (capacitance)×V (voltage). That is, by switching on and off the conversion efficiency switching transistor 156, the conversion efficiency can be switched, and thus the saturation signal amount can be increased at the time of high illuminance, and the PD 152 can be prevented from overflowing.

The reset transistor 158 can reset the charges accumulated in the FD section 154 and the charges accumulated in the capacitor 157 by resetting a potential of the FD section 154 to a predetermined potential.

Note that the circuit configuration of the pixel circuit 41 of the pixel 21 according to the present disclosure is not limited to the configuration illustrated in FIG. 3, and for example, some pixel transistors may be omitted or pixel transistors may be added.

In addition, as illustrated in FIG. 3, the pixel 21 includes transistors 155, 159, 160, 161, 162, 163, and 165 as the comparator 61.

An input bias current Vb is supplied to the transistor 159, and the reference signal REF is supplied to the transistor 160. The transistor 160 constitutes a differential input circuit together with the above-described amplification transistor 155 to which the input signal SIG is supplied. The differential input circuit compares the input signal SIG with the reference signal REF. In addition, the transistors 161 and 162 constitute a current mirror, are connected to a power supply line (VDDHPX) 167, and equally supply currents to the pair of transistors 155 and 160 constituting the differential input circuit. The transistor 163 supplies the output signal VCO of the differential input circuit to the transistor 165. The transistor 165 functions as a voltage conversion circuit, and outputs the converted signal to the positive feedback circuit 62 (see FIG. 2).

Note that the circuit configuration of the comparator 61 of the pixel 21 according to the present disclosure is not limited to the circuit configuration illustrated in FIG. 3.

Note that, in the present disclosure, for example, the pixel circuit 41 and a part of the comparator 61 (specifically, the components constituting the comparator 61 illustrated below the node 170 in FIG. 3) of the pixel 21 may be formed on an image sensor-side substrate. Furthermore, the remaining components of the comparator 61 (specifically, the components constituting the comparator 61 illustrated above the node 170 in FIG. 3) may be formed on a logic circuit substrate stacked on the image sensor-side substrate. Then, the image sensor-side substrate and the logic circuit substrate are bonded and electrically connected by a bonding electrode made of copper (Cu) or the like.

### <1.4 Background>

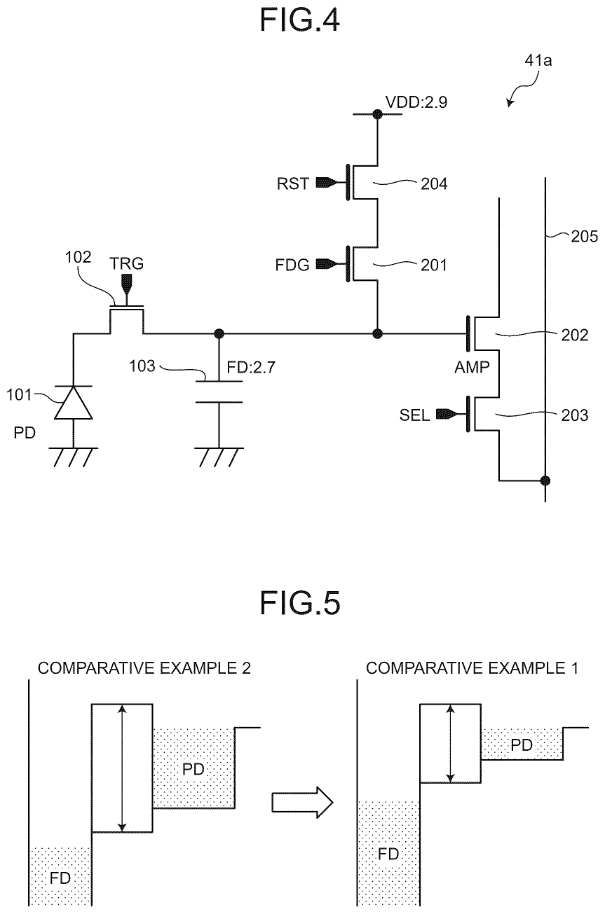

Next, the background to the creation of the embodiments of the present disclosure by the inventor will be described with reference to FIGS. 4 and 5. FIG. 4 is a circuit diagram illustrating a circuit configuration example of a pixel according to Comparative Example 2, and FIG. 5 is an explanatory diagram for describing the background of the embodiments of the present disclosure. Note that, in the following description, Comparative Example 1 means the imaging device 1 having the configuration as illustrated in FIGS. 1 to 3, that is, the imaging device in which the ADC 42 (comparator 61) is provided for each pixel 21. In addition, Comparative Example 2 means a column ADC type imaging device having the circuit configuration as illustrated in FIG. 4 in which the ADC is arranged for each pixel column. Here, the comparative example means an imaging device that had been studied by the inventor before creating the embodiments of the present disclosure.

The basic circuit configuration of the pixel of Comparative Example 2 illustrated in FIG. 4 is the same as the configuration of the pixel circuit 41 illustrated in FIG. 3, and the pixel transistors having the same name in FIGS. 3 and 4 have the same functions. Specifically, PD 101 in FIG. 4 corresponds to the PD 152 in FIG. 3, a transfer transistor (TRG) 102 in FIG. 4 corresponds to the transfer transistor 153 in FIG. 3, and FD section 103 in FIG. 4 corresponds to the FD section 154 in FIG. 3. Furthermore, the conversion efficiency switching transistor (FDG) 201 in FIG. 4 corresponds to the conversion efficiency switching transistor 156 in FIG. 3, the amplification transistor (AMP) 202 in FIG. 4 corresponds to the amplification transistor 155 in FIG. 3, and the reset transistor (RST) 204 in FIG. 4 corresponds to the reset transistor 158 in FIG. 3.

Furthermore, a selection transistor (SEL) 203 illustrated in FIG. 4 is connected to a terminal of the amplification transistor 202. When the selection transistor 203 is turned on, the amplification transistor 202 outputs a voltage corresponding to a potential of the FD section 103 that accumulates charges to a column signal processing circuit (not illustrated) via a vertical signal line 205.

In addition, in FIG. 4, unlike the circuit configuration example of FIG. 3, a capacitor corresponding to the capacitor 157 of FIG. 3 is not provided. However, for example, when the conversion efficiency switching transistor 201 is turned on, a gate capacitance of the conversion efficiency switching transistor 201 increases and the gate capacitance works similarly to the capacitor 157, and thus the conversion efficiency can be switched. Note that the capacitor 157 may be provided in the circuit configuration of FIG. 4.

Since the imaging device 1 of Comparative Example 1 has the circuit configuration as illustrated in FIG. 3, when reset is performed by the reset transistor 158, the potential of the FD section 154 is lower than that of the column ADC type imaging device of Comparative Example 2 in which the ADC is arranged for each pixel column.

Specifically, when turned on, the reset transistor 158 resets the charges accumulated in the FD section 154 by resetting the potential of the FD section 154 to a potential VDD on the power supply line side (power supply potential). In the imaging device 1 of Comparative Example 1, the transistors 161 and 162 constituting the current mirror circuit of the comparator 61 are connected to the power supply line 167 having the power supply potential VDD (for example, 2.9 V). In addition, the reset transistor 158 is connected to the current mirror circuit of the comparator 61. Therefore, the reset transistor 158 resets the potential of the FD section 154 to a potential lower than the power supply potential VDD (for example, 1.8 V) due to the presence of the current mirror circuit, the reset transistor 158, and the like.

On the other hand, since the imaging device of Comparative Example 2 has the circuit configuration illustrated in FIG. 4, when the reset transistor 204 is turned on, the charges accumulated in the FD section 103 are reset by resetting the potential of the FD section 103 to a potential (for example, 2.7 V) close to the power supply potential VDD (for example, 2.9 V). Therefore, in the imaging device 1 of Comparative Example 1, the potential of the FD section 154 when reset is performed by the reset transistor 158 is lower than that in the imaging device of Comparative Example 2.

FIG. 5 schematically illustrates the amount of charges accumulated in the PD 101 and the PD 152. In Comparative Example 2 illustrated on the left side of FIG. 5, the reset transistor 204 resets the potential of the FD section 103 to a value close to the power supply potential VDD. Therefore, in Comparative Example 2, as illustrated on the left side of FIG. 5, the amount of charges remaining in the FD section 103 at the time of resetting decreases, and thus, the FD section 103 can receive a large amount of charges from the PD 101.

On the other hand, in Comparative Example 1 illustrated on the right side of FIG. 5, the reset transistor 158 resets the potential of the FD section 154 to a value lower than the power supply potential VDD. Therefore, in Comparative Example 1, as illustrated on the right side of FIG. 5, the amount of charges remaining in the FD section 154 at the time of resetting increases, and thus, it is difficult for the FD section 154 to receive a large amount of charges from the PD 152.

When the illuminance is high, a large amount of charges are generated in the PD 152, but the charges are immediately saturated in the FD section 154 of Comparative Example 1. In such a case, for example, blown-out highlights occur in an image obtained by the imaging device 1, or a dynamic range becomes narrow. As described above, in the imaging device 1 of Comparative Example 1, the capacitor 157 is provided, and the conversion efficiency is switched by the conversion efficiency switching transistor 156 at the time of high illuminance to suppress charge saturation. However, the capacitance of the capacitor 157 is small, causing a limitation on avoiding charge saturation. That is, the problem is that, in Comparative Example 1, which is the imaging device 1 in which the ADC 42 (comparator 61) is provided for each pixel 21, the saturation signal amount of the pixel 21 is low as compared with Comparative Example 2, which is a column ADC type imaging device in which the ADC is arranged for each pixel column.

As a result, in view of such a situation, the present inventor has created embodiments of the present disclosure described below. In the embodiments of the present disclosure, in the imaging device 1 in which the ADC 42 (comparator 61) is provided for each pixel 21, it is possible to accumulate more charges overflowing through the FD section 154 by using a high-capacitance element for the capacitor 157. By doing so, according to the embodiments of the present disclosure, it is possible to further reduce the conversion efficiency at the time of high illuminance, and to increase the saturation signal amount of the pixel 21. Hereinafter, the details of the embodiments of the present disclosure created by the present inventors will be sequentially described.

### 2. First Embodiment

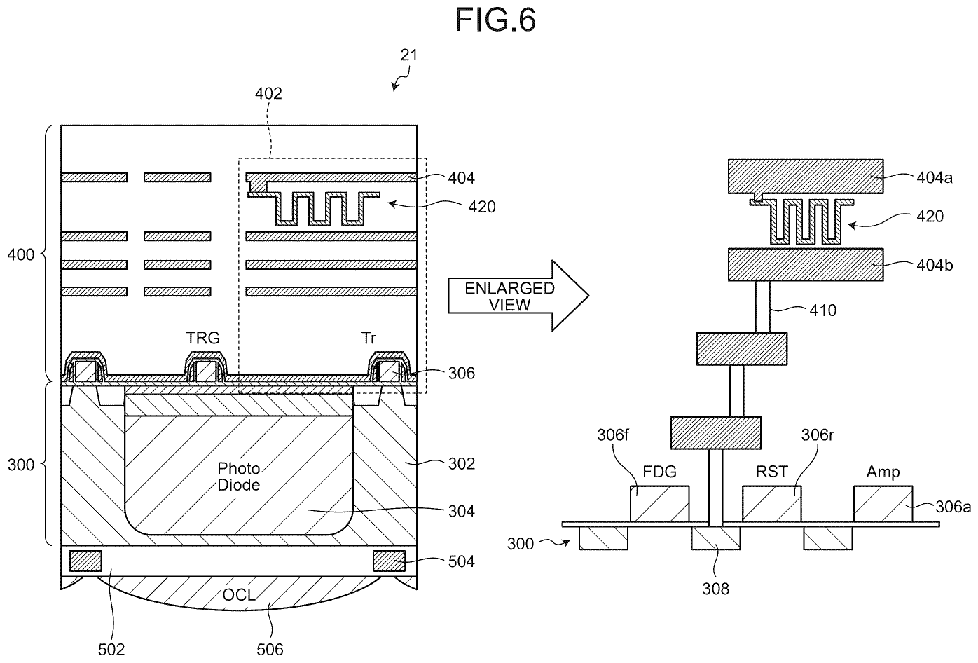

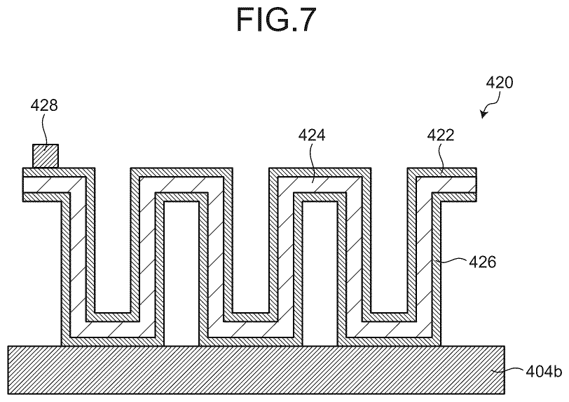

First, a first embodiment of the present disclosure will be described with reference to FIGS. 6 and 7. FIG. 6 is a diagram illustrating a cross-sectional configuration example of the pixel 21 of the present embodiment, and FIG. 7 is a partially enlarged view of FIG. 6. In the present embodiment, the capacitance can be increased by using a three-dimensional metal insulator metal (MIM) capacitor for the above-described capacitor 157. As a result, according to the present embodiment, it is possible to reduce the conversion efficiency and increase the saturation signal amount of the pixel 21. Hereinafter, a detailed configuration of the pixel 21 according to the present embodiment will be described. Note that the pixel 21 of the present embodiment has the circuit configuration illustrated in FIG. 3.

Specifically, as illustrated in the left diagram of FIG. 6, the pixel 21 according to the present embodiment mainly includes a semiconductor substrate 300 made of, for example, silicon and a wiring layer 400 provided on an upper surface of the semiconductor substrate 300. Note that FIG. 6 schematically illustrates only a main part of the pixel 21.

The semiconductor substrate 300 is made of, for example, a silicon substrate. For example, a PD (photoelectric conversion section) 304 having impurities of the first conductivity type (for example, n type) is provided for each pixel 21 in a region 302 having impurities of the second conductivity type (for example, p type) in the semiconductor substrate 300. In addition, although not illustrated in FIG. 6, an FD section containing impurities having the same first conductivity type as the PD 304 at a higher concentration than the PD 304 is provided in the semiconductor substrate 300.

Note that, in the present specification, the pixel 21 in which the first conductivity type is n-type, the second conductivity type is p-type, and electrons are used as signal charges will be described, but the present embodiment is not limited to such an example. For example, the present embodiment can also be applied to the pixel 21 in which the first conductivity type is p-type, the second conductivity type is n-type, and holes are used as signal charges.

Furthermore, in the present embodiment, the adjacent PDs 304 may be physically separated by a pixel separation section (not illustrated). The pixel separation section includes a groove (trench) provided as a penetrating deep trench isolation (DTI) so as to penetrate the semiconductor substrate 300 along a film thickness direction of the semiconductor substrate 300, an insulating film such as silicon oxide (SiO₂) embedded in the trench, and the like.

In addition, a light shielding film 504 that suppresses leakage of light to the adjacent PD 304 is formed on the back surface side (lower side in the left diagram of FIG. 6) of the semiconductor substrate 300. The light shielding film 504 is made of, for example, a metal film such as tungsten (W). Furthermore, a planarization film 502 made of silicon oxide or the like is provided on the back surface of the semiconductor substrate 300. An on-chip lens (OCL) 506 made of a styrene-based resin, an acryl-based resin, a styrene-acrylic copolymer-based resin, a siloxane-based resin, or the like on which light from the outside is incident is provided on the planarization film 502.

In addition, a pixel transistor 306 such as the transfer transistor (TRG) (specifically, an amplification transistor (AMP) 306a, a conversion efficiency switching transistor (FDG) 306f, a reset transistor (RST) 306r, and the like as illustrated in the right diagram of FIG. 6) is provided on a front surface side of the semiconductor substrate 300 (the upper side of the left diagram of FIG. 6). The pixel transistor 306 has, for example, a gate electrode made of a polysilicon (Poly-Si) film or the like provided on a surface of the semiconductor substrate 300 via a gate insulating film (not illustrated).

Furthermore, a wiring layer 400 is provided on the front surface side of the semiconductor substrate 300. The wiring layer 400 includes, for example, an insulating film 402 made of silicon oxide or the like, and wiring 404 made of aluminum (Al) or the like. In the present embodiment, a three-dimensional MIM capacitor 420 functioning as the above-described capacitor 157 is provided in the wiring layer 400.

Specifically, as illustrated in the right diagram of FIG. 6 obtained by enlarging the wiring layer 400 in the left diagram of FIG. 6, the three-dimensional MIM capacitor 420 is provided between wirings 404a and 404b of the wiring layer 400. Specifically, in the wiring layer 400, a plurality of wirings 404 are provided through a plurality of layers along a stacking direction of a stacked structure, and the wirings 404 are electrically connected to each other by a through via 410 or the like penetrating the insulating film 402. One terminal of the three-dimensional MIM capacitor 420 provided between the wirings 404a and 404b of the wiring layer 400 is electrically connected to the wiring 404a located on the three-dimensional MIM capacitor 420. The other terminal of the three-dimensional MIM capacitor 420 is electrically connected to the wiring 404b located below the three-dimensional MIM capacitor 420. Furthermore, the wiring 404b is electrically connected to a diffusion region 308 in the semiconductor substrate 300 that is shared by the reset transistor 306r and the conversion efficiency switching transistor 306f as a source/drain.

The three-dimensional MIM capacitor 420 has a three-dimensional structure, and thus can increase the capacitance as compared with a capacitor structure including a pair of parallel flat plates sandwiching a dielectric. In the present embodiment, the structure of the three-dimensional MIM capacitor 420 is not particularly limited as long as it has a three-dimensional structure. Although the three-dimensional MIM capacitor 420 has a three-dimensional structure, it can be formed by a relatively simple process, and thus, it can be said that the three-dimensional MIM capacitor 420 has a structure capable of easily obtaining a large-capacity capacitor.

In the present embodiment, for example, as illustrated in FIG. 7, the three-dimensional MIM capacitor 420 has a stacked structure including a pair of metal layers 422 and 426 sandwiching a dielectric layer (insulating layer) 424, and has a cross-sectional shape of a substantially rectangular wave. The metal layers 422 and 426 can be formed of, for example, titanium nitride (TiN) or the like, and the dielectric layer 424 can be formed of, for example, silicon nitride (Si₃N₄) or the like. In addition, a contact 428 for electrically connecting the wiring 404a and the upper metal layer 422 can be formed of, for example, an aluminum alloy or the like. Furthermore, the metal layer 422 is electrically connected to the power supply, the ground, or the well region of the semiconductor substrate 300 via the wiring 404a (note that FIG. 3 is a circuit diagram in a case where the capacitor 157 is connected to the ground). In addition, the metal layer 426 is provided so as to be in contact with the wiring 404b and thus is electrically connected to the wiring 404b. Furthermore, the metal layer 426 is electrically connected to the diffusion region 308 shared by the reset transistor 306r and the conversion efficiency switching transistor 306f via the wiring 404b.

In the example of FIG. 7, since the three-dimensional MIM capacitor 420 has a cross-sectional shape of a substantially rectangular wave, a facing area where the pair of metal layers 422 and 426 face each other becomes wider, and thus it is possible to increase the capacitance while keeping the volume occupied by the three-dimensional MIM capacitor 420 small.

As described above, in the present embodiment, the capacitance can be increased by using the three-dimensional MIM capacitor 420 for the capacitor 157. As a result, according to the present embodiment, the capacitor 157 has a high capacitance and thus it is possible to reduce the conversion efficiency at the time of high illuminance, and to increase the saturation signal amount of the pixel 21.

### 3. Second Embodiment

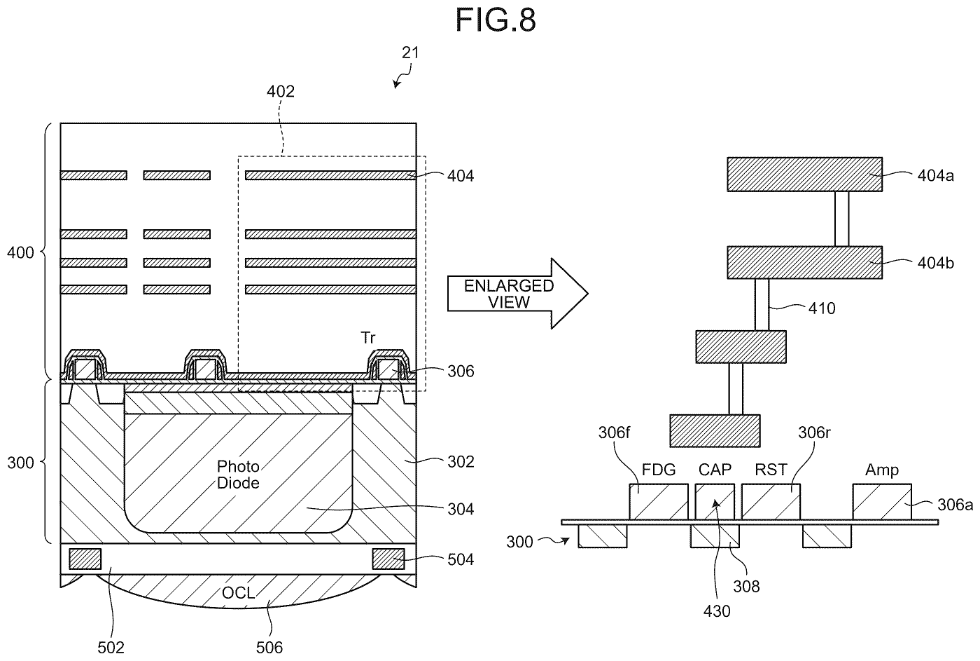

Next, a second embodiment of the present disclosure will be described with reference to FIG. 8. FIG. 8 is a diagram illustrating a cross-sectional configuration example of the pixel 21 of the present embodiment. In the present embodiment, the capacitance can be increased by using a metal oxide semiconductor (MOS) capacitor for the above-described capacitor 157. As a result, according to the present embodiment, it is possible to reduce the conversion efficiency at the time of high illuminance and increase the saturation signal amount of the pixel 21. Hereinafter, a detailed configuration of the pixel 21 according to the present embodiment will be described.

Specifically, as illustrated in the left diagram of FIG. 8, the pixel 21 according to the present embodiment, as in the first embodiment, mainly includes the semiconductor substrate 300 made of, for example, silicon and the wiring layer 400 provided on the upper surface of the semiconductor substrate 300. In addition, the pixel 21 of the present embodiment has the circuit configuration illustrated in FIG. 3. Note that the components other than a MOS capacitor 430 are common to those of the first embodiment, and thus description thereof is omitted here.

In the present embodiment, as illustrated in the right diagram of FIG. 8 obtained by enlarging the wiring layer 400 in the left diagram of FIG. 8, the MOS capacitor 430 functioning as the above-described capacitor 157 is provided on the surface of the semiconductor substrate 300 (an upper side of the left diagram of FIG. 8). The MOS capacitor 430 is provided on the diffusion region 308 in the semiconductor substrate 300 shared by the reset transistor (RST) 306r and the conversion efficiency switching transistor (FDG) 306f. Specifically, the MOS capacitor 430 includes a stack of an electrode made of a metal film or a poly silicon film provided on the surface of the semiconductor substrate 300, which is the same as the gate electrode of the pixel transistor 306, an insulating film (oxide film) made of, for example, a silicon oxide film provided below the electrode, and the diffusion region 308. In the MOS capacitor 430, the capacitance can be increased by increasing the area of the interface of the stack. That is, in the present embodiment, the capacitance can be increased by increasing the area of the electrode (the area in contact with the semiconductor substrate 300). Furthermore, in the present embodiment, the capacitance can be further increased by reducing the film thickness of the insulating film or forming the insulating film using a material having a high relative dielectric constant (hafnium oxide (HfO₂)).

As described above, in the present embodiment, the capacitance can be increased by using the MOS capacitor 430 for the capacitor 157. As a result, according to the present embodiment, the capacitor 157 has a high capacitance and thus it is possible to reduce the conversion efficiency at the time of high illuminance, and to increase the saturation signal amount of the pixel 21. In addition, the MOS capacitor 430 can be formed simultaneously with the pixel transistor 306, and thus, in the present embodiment, it is possible to avoid increasing the manufacturing process of the imaging device 1 even if the capacitor 157 is made of the MOS capacitor 430.

### 4. Third Embodiment

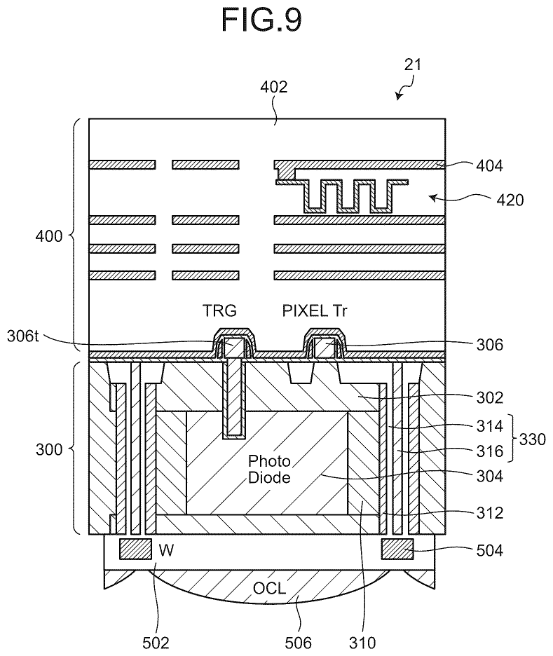

Next, a second embodiment of the present disclosure will be described with reference to FIG. 9. FIG. 9 is a diagram illustrating a cross-sectional configuration example of the pixel 21 of the present embodiment. In the present embodiment, a capacitor is added to the configuration of the first embodiment by solid-phase diffusion of impurities to a side wall of the PD 304, thereby making it possible to increase the amount of accumulated charges of the PD 304 itself, and to further increase the saturation signal amount of the pixel 21. Hereinafter, a detailed configuration of the pixel 21 according to the present embodiment will be described.

Specifically, as illustrated in FIG. 9, the pixel 21 according to the present embodiment, as in the first embodiment, mainly includes the semiconductor substrate 300 made of, for example, silicon and the wiring layer 400 provided on the upper surface of the semiconductor substrate 300. In addition, the pixel 21 of the present embodiment has the circuit configuration illustrated in FIG. 3. Note that provided components other than the semiconductor substrate 300 are common to those of the first embodiment, and thus description thereof is omitted here.

As illustrated in FIG. 9, also in the present embodiment, the PD 304 having impurities of the first conductivity type (for example, n type) is provided in the region 302 having impurities of the second conductivity type (for example, p type) in the semiconductor substrate 300, as in the first embodiment. In addition, the PD 304 is separated and partitioned for each pixel 21 by a pixel separation section 320. As described above, the pixel separation section 320 includes, as the penetrating DTI, a trench provided so as to penetrate the semiconductor substrate 300 along the film thickness direction of the semiconductor substrate 300, a silicon oxide film 314 covering a sidewall of the trench, and the polysilicon film 316 embedded in the trench.

Furthermore, in the present embodiment, a solid-phase diffusion layer (diffusion region) 312 having impurities of the second conductivity type (for example, p-type) and a solid-phase diffusion layer 310 having impurities of the first conductivity type (for example, n-type) are provided between the PD 304 and the pixel separation section 320 in order from the pixel separation section 320 side toward the PD 304. By providing such solid-phase diffusion layers 310 and 312, a strong electric field region is generated in the PN junction portion, and the region can hold charges generated by the PD 304 as a capacitor. Therefore, according to the present embodiment, since more generated charges can be held, the amount of accumulated charges of the PD 304 increases, and as a result, the saturation signal amount of the pixel 21 can be further increased.

In addition, the solid-phase diffusion layers 310 and 312 are layers formed by solid-phase diffusion to be described below, and are formed by diffusing impurities from the trench when forming the pixel separation section 320. The solid-phase diffusion is one of conformal doping methods that can uniformly introduce impurities into a semiconductor, and the impurities can be uniformly introduced than in an ion implantation method.

For example, the trench is formed so as to penetrate along the thickness direction of the semiconductor substrate 300. Then, a silicon oxide film containing n-type impurities is formed at an inner side of the trench, and heat treatment is performed to dope impurities from the silicon oxide film to the semiconductor substrate 300 side (solid-phase diffusion). Next, the silicon oxide film containing the n-type impurities in the trench is removed, and heat treatment is performed again to diffuse the impurities into the semiconductor substrate 300, thereby forming the solid-phase diffusion layer 310.

Further, a silicon oxide film containing p-type impurities is formed at the inner side of the trench, and heat treatment is performed to dope impurities from the silicon oxide film to the semiconductor substrate 300 side (solid-phase diffusion), thereby forming the solid-phase diffusion layer 312. Further, the silicon oxide film containing the n-type impurities in the trench is removed, and the silicon oxide film 314 and the polysilicon film 316 are formed in the trench to form the pixel separation section 320.

Note that, in the present embodiment, the solid-phase diffusion layer 310 having impurities of the first conductivity type (for example, n-type) is not limited to the one formed by the above-described solid-phase diffusion, and may be formed by implanting impurities by the ion implantation method.

In addition, in the present embodiment, as illustrated in FIG. 9, a gate electrode of a transfer transistor 306t may have an embedded gate portion embedded in the semiconductor substrate 300. The embedded gate portion can be formed, for example, by forming a trench by etching from the front surface side of the semiconductor substrate 300, forming a gate insulating film, and further embedding a polysilicon film or the like in the trench. Then, by applying a voltage to the embedded gate portion via the gate electrode of the transfer transistor 306t, a potential of a semiconductor region around the embedded gate portion can be efficiently modulated. Furthermore, charges generated by the PD 304 at a deep portion of the semiconductor substrate 300 pass through the region modulated by the embedded gate portion and are transferred to the FD section 154. Therefore, the potential can be effectively modulated by such an embedded gate portion, and thus charges can be efficiently transferred.

As described above, in the present embodiment, a capacitor is added by solid-phase diffusion of impurities to the side wall of the PD 304, thereby making it possible to increase the amount of accumulated charges of the PD 304 itself, and to further increase the saturation signal amount of the pixel 21.

### 5. Fourth Embodiment

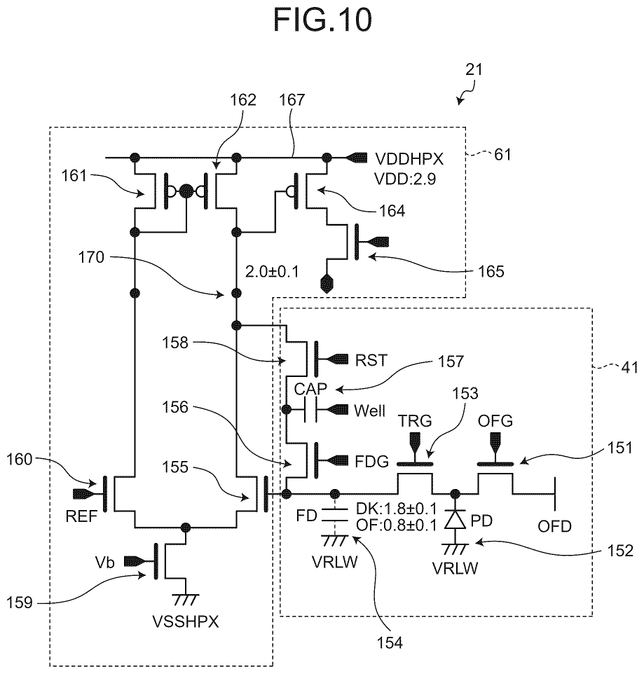

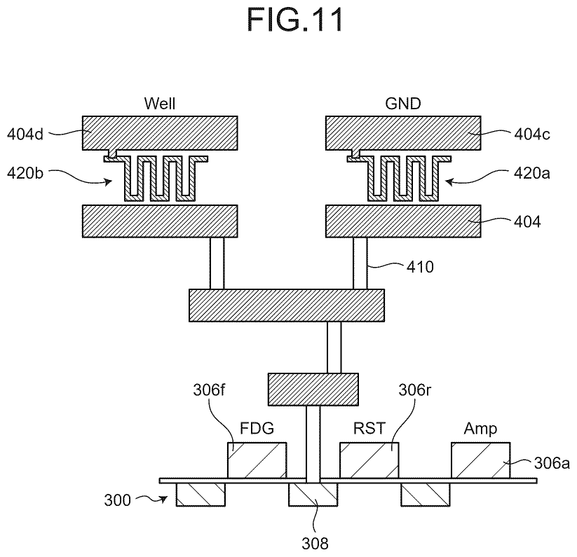

In the embodiment of the present disclosure, the connection destination of the capacitor 157 is not limited to the ground, and may be the power supply or the well region of the semiconductor substrate 300. In addition, in the embodiment of the present disclosure, the capacitor 157 is not limited to one capacitor, and may be made of two or more capacitors. Thus, such an embodiment will be described as a fourth embodiment of the present disclosure with reference to FIGS. 10 and 11. FIG. 10 is a circuit diagram illustrating a circuit configuration example of a pixel according to the present embodiment, and FIG. 11 is a diagram illustrating a cross-sectional configuration example of the pixel of the present embodiment.

In FIG. 3, the one terminal of the capacitor 157 is connected to the ground, but in the example illustrated in FIG. 10, the one terminal of the capacitor 157 is electrically connected to the well region of the semiconductor substrate 300. Note that, in the present embodiment, the connection destination of the one terminal of the capacitor 157 is not limited to the ground or the well region, and the one terminal of the capacitor 157 may be electrically connected to a power supply, that is, the power supply line 167.

In the example of FIG. 11, two three-dimensional MIM capacitors 420a and 420b are used for the capacitor 157, and the two three-dimensional MIM capacitors 420a and 420b may be electrically connected to different portions. Specifically, one three-dimensional MIM capacitor 420a is electrically connected to wiring 404c connected to the ground, and the other three-dimensional MIM capacitor 420b is electrically connected to wiring 404d connected to the well region. In other words, in the present embodiment, two or more three-dimensional MIM capacitors 420 can be used for the capacitor 157. Furthermore, in the present embodiment, the plurality of three-dimensional MIM capacitors 420 may be electrically connected to different destinations selected from the power supply, the ground, or the well region.

Note that, in the present embodiment, the plurality of three-dimensional MIM capacitors 420 constituting the capacitor 157 may be electrically connected to the same one selected from the power supply, the ground, or the well region.

Furthermore, in the example of FIG. 11, the two three-dimensional MIM capacitors 420a and 420b are used for the capacitor 157, but the present embodiment is not limited thereto, and a plurality of MOS capacitors 430 may be used for the capacitor 157. Also in this case, the plurality of MOS capacitors 430 may be electrically connected to different destinations selected from the power supply, the ground, or the well region, or may be electrically connected to the same one.

### 6. Fifth Embodiment

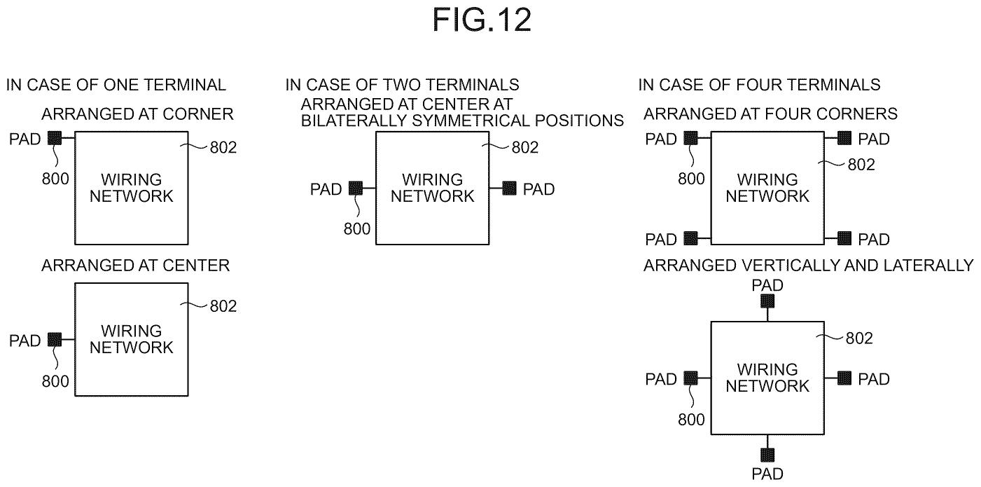

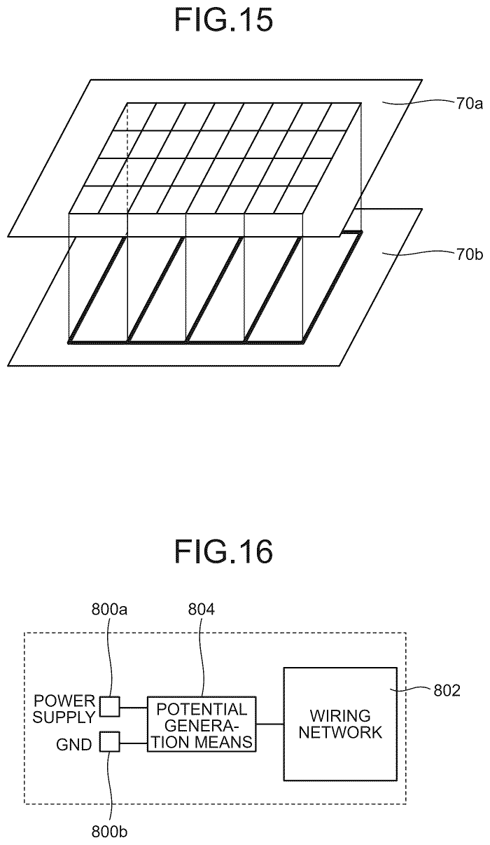

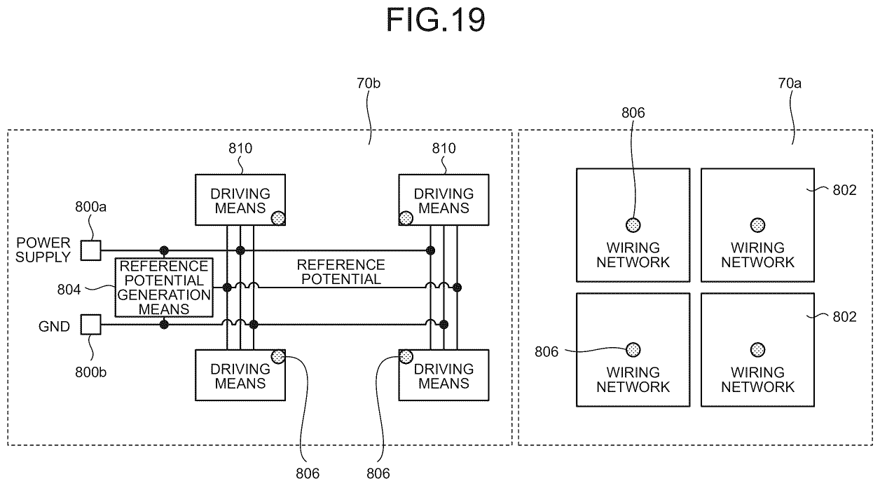

In the embodiments of the present disclosure, a pad (connection pad) provided on the substrate for connecting the one terminal of the capacitor 157 to the ground or the like may be provided for each wiring network formed by a circuit for each pixel 21. Alternatively, in the embodiments of the present disclosure, one or a plurality of pads may be provided for each wiring network unit. Thus, such an embodiment and a modification thereof will be described as a fifth embodiment of the present disclosure with reference to FIGS. 12 and 19. FIGS. 12, 13, and 16 to 19 are explanatory diagrams for explaining a positional relationship between the wiring network and the pad according to the present embodiment, and FIGS. 14 and 15 are explanatory diagrams for explaining an example of the wiring network according to the present embodiment.

First, as illustrated on the left side of FIG. 12 (in the case of one terminal), in the present embodiment, a pad 800 provided on the substrate for connection to the ground or the like may be provided for each wiring network 802 formed by the circuit of the pixel 21. Furthermore, the pad 800 may be arranged on the substrate so as to be adjacent to a corner of a region where the wiring network 802 is provided, or may be arranged so as to be adjacent to a center of one side of the region of the wiring network 802.

Furthermore, as illustrated in the center of FIG. 12 (in the case of two terminals), in the present embodiment, two pads 800 may be provided for each wiring network 802. Furthermore, the two pads 800 may be provided at bilaterally symmetrical positions so as to be adjacent to the center of the one side of the region of the wiring network 802 and to sandwich the region of the wiring network 802.

In addition, as illustrated on the right side of FIG. 12 (in the case of four terminals), in the present embodiment, four pads 800 may be provided for each wiring network 802.

Furthermore, as illustrated on the upper right side of FIG. 12, the four pads 800 may be provided at bilaterally symmetrical positions so as to be adjacent to the corner of the region of the wiring network 802 and to sandwich the region of the wiring network 802. In addition, as illustrated on the lower right side of FIG. 12, the four pads 800 may be provided at vertically and bilaterally symmetrical positions so as to be adjacent to the center of the one side of the region of the wiring network 802 and to vertically and laterally sandwich the region of the wiring network 802.

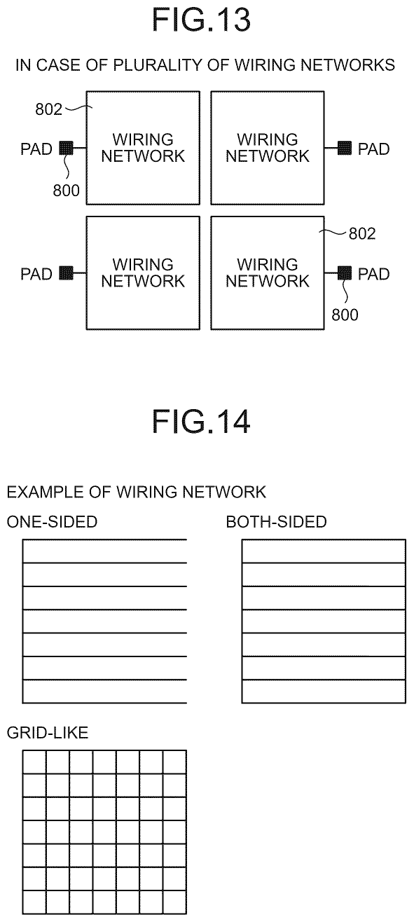

In addition, as illustrated in FIG. 13, the circuit of one pixel 21 may include a plurality of (4 in the example of FIG. 13) wiring networks 802. In such a case, the pad 800 may be provided for each wiring network 802.

In the present embodiment, a wiring pattern of the wiring network 802 is not particularly limited. For example, in the present embodiment, as illustrated in the upper left side of FIG. 14, the wiring network 802 may include a plurality of stripe-shaped wirings extending along the left-right direction of the substrate, and may be connected to each other on one side of each stripe-shaped wiring. Alternatively, in the present embodiment, as illustrated in the upper right side of FIG. 14, the wiring network 802 may be connected to each other on both sides of each stripe-shaped wiring. Furthermore, in the present embodiment, as illustrated in the lower side of FIG. 14, the wiring network 802 may include grid-like wiring.

Furthermore, the wiring network 802 constituting the circuit of the pixel 21 may be provided across two stacked substrates 70a and 70b as illustrated in FIG. 15. In this case, wiring on the substrate 70a side and wiring on the substrate 70b side may be electrically connected by a through via (not illustrated).

Furthermore, in the present embodiment, pads 800a and 800b are not limited to the ones directly connected to the wiring network 802, and may be connected to the wiring network 802 via a circuit constituting a potential generation means 804 (hereinafter, referred to as potential generation means), as illustrated in FIG. 16. Here, the pad 800a is a pad connected to the power supply, and the pad 800b is a pad connected to the ground. In addition, the potential generation means 804 can include, for example, a circuit configuration that generates a reference potential and a drive circuit that is electrically connected to the circuit configuration that generates the reference potential and drives the pixel 21.

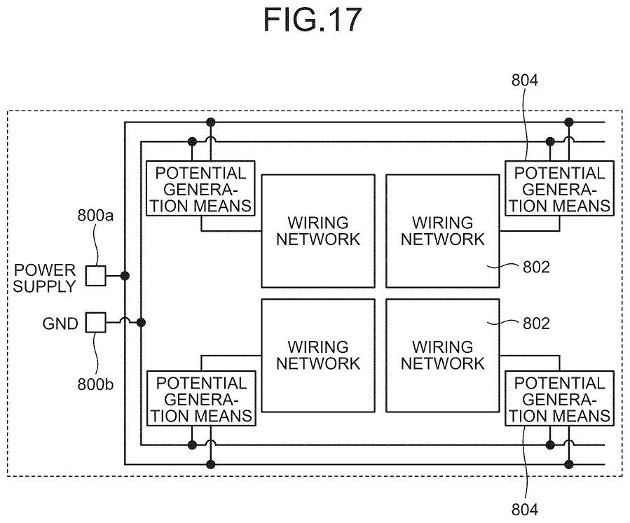

In addition, in the present embodiment, as illustrated in FIG. 17, the circuit of one pixel 21 may include the plurality of wiring networks 802. In such a case, the potential generation means 804 may be provided for each wiring network 802, and each potential generation means 804 may be connected to the pad 800a connected to the power supply and the pad 800b connected to the ground.

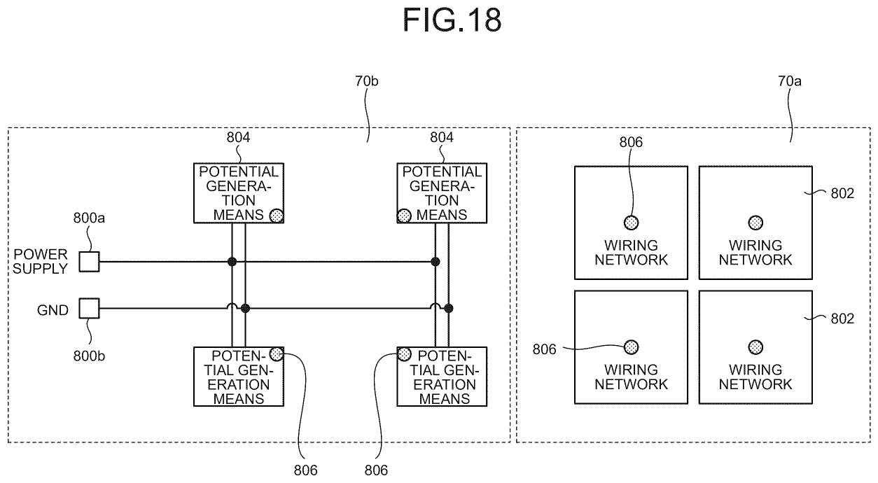

In addition, in the present embodiment, the configuration may be modified to one in which the configuration example of FIG. 17 is provided across the two stacked substrates 70a and 70b. Specifically, in the present embodiment, as illustrated in FIG. 18, the plurality of wiring networks 802 are provided on one substrate 70a, and the pads 800a and 800b and the potential generation means 804 are provided on the other substrate 70b. In the present embodiment, the wiring network 802 and the potential generation means 804 that are provided on the different substrates 70a and 70b are electrically connected by a through via 806. Note that, in FIG. 18, the wiring network 802 and the potential generation means 804 are connected by one through via 806, but the present embodiment is not limited thereto, and the wiring network 802 and the potential generation means 804 may be connected by a plurality of through vias 806. In addition, in FIG. 18, the plan views of the two substrates 70a and 70b are illustrated side by side along the left-right direction.

Furthermore, in the present embodiment, a circuit 810 constituting a driving section that drives the pixel 21 (hereinafter, referred to as a driving means) may be provided in the configuration example of FIG. 18. Specifically, in the present embodiment, as illustrated in FIG. 19, the plurality of wiring networks 802 are provided on one substrate 70a, and the pads 800a and 800b, the potential generation means 804, and the driving means 810 are provided on the other substrate 70b. In the present embodiment, the wiring network 802 and the driving means 810 that are provided on the different substrates 70a and 70b are electrically connected by the through via 806. The driving means 810 is provided for each wiring network 802. Furthermore, each driving means 810 may be connected to the potential generation means 804, the pad 800a connected to the power supply, and the pad 800b connected to the ground.

### 7. Summary

As described above, according to the embodiments of the present disclosure, it is possible to increase the saturation signal amount in the configuration in which the ADC 42 is provided for each pixel 21.

In addition, the imaging device 1 according to the embodiments of the present disclosure can be manufactured by using methods, equipment, and conditions used for manufacturing a general semiconductor device. That is, the imaging device 1 according to the present embodiment can be manufactured using an existing semiconductor device manufacturing process.

Note that examples of the above-described methods include a physical vapor deposition (PVD) method, a chemical vapor deposition (CVD) method, and an atomic layer deposition (ALD) method. Examples of the PVD method can include a vacuum vapor deposition method, an electron beam (EB) vapor deposition method, various sputtering methods (a magnetron sputtering method, a radio frequency (RF)-direct current (DC) coupled bias sputtering method, an electron cyclotron resonance (ECR) sputtering method, a counter target sputtering method, a high frequency sputtering method, and the like), an ion plating method, a laser ablation method, a molecular beam epitaxy (MBE) method, and a laser transfer method. Examples of the CVD method can include a plasma CVD method, a thermal CVD method, an organic metal (MO) CVD method, and a photo-CVD method. Furthermore, other methods can include an electrolytic plating method, an electroless plating method, and a spin coating method; an immersion method; a cast method; a micro-contact printing method; a drop cast method; various printing methods such as a screen printing method, an inkjet printing method, an offset printing method, a gravure printing method, and a flexographic printing method; a stamping method; a spray method; and various coating methods such as an air doctor coater method, a blade coater method, a rod coater method, a knife coater method, a squeeze coater method, a reverse roll coater method, a transfer roll coater method, a gravure coater method, a kiss coater method, a cast coater method, a spray coater method, a slit orifice coater method, and a calendar coater method. Furthermore, examples of the patterning method can include chemical etching such as shadow mask, laser transfer, and photolithography, and physical etching using ultraviolet rays, laser, and the like. In addition, examples of the planarization technique can include a chemical mechanical polishing (CMP) method, a laser planarization method, a reflow method, and the like.

Furthermore, the above-described imaging device 1 is one example of a light detection device to which the technique according to the present disclosure can be applied. That is, the technique according to the present disclosure is not limited to the one applied to the imaging device, and can be applied to, for example, a device that detects light (light detection device) such as a distance measuring device or an inspection device using light.

### 8. Application Example

### <8.1 Application Example to a Camera>

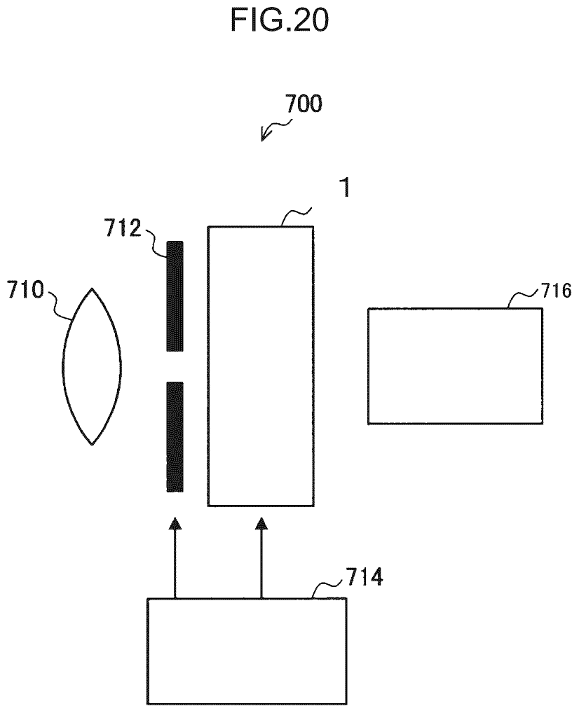

The technique according to the present disclosure (present technique) can be further applied to various products. For example, the technique according to the present disclosure may be applied to a camera or the like. Thus, a configuration example of a camera 700 as an electronic apparatus that applies the present technique will be described with reference to FIG. 20. FIG. 20 is an explanatory diagram illustrating an example of a schematic functional configuration of the camera 700 to which the technique according to the present disclosure (the present technique) can be applied.

As illustrated in FIG. 20, the camera 700 includes the imaging device 1, an optical lens 710, a shutter mechanism 712, a drive circuit unit 714, and a signal processing circuit unit 716. The optical lens 710 forms an image of image light (incident light) from a subject on an imaging surface of the imaging device 1. As a result, signal charges are accumulated in an imaging element 100 of the imaging device 1 for a certain period. The shutter mechanism 712 opens and closes to control a light irradiation period and a light shielding period for the imaging device 1. The drive circuit unit 714 supplies drive signals for controlling a signal transfer operation of the imaging device 1, a shutter operation of the shutter mechanism 712, and the like to these devices. That is, the imaging device 1 performs signal transfer based on the drive signal (timing signal) supplied from the drive circuit unit 714. The signal processing circuit unit 716 performs various types of signal processing. For example, the signal processing circuit unit 716 outputs a video signal subjected to the signal processing to, for example, a storage medium (not illustrated) such as a memory, or to a display unit (not illustrated).

### <8.2 Application Example to a Smartphone>

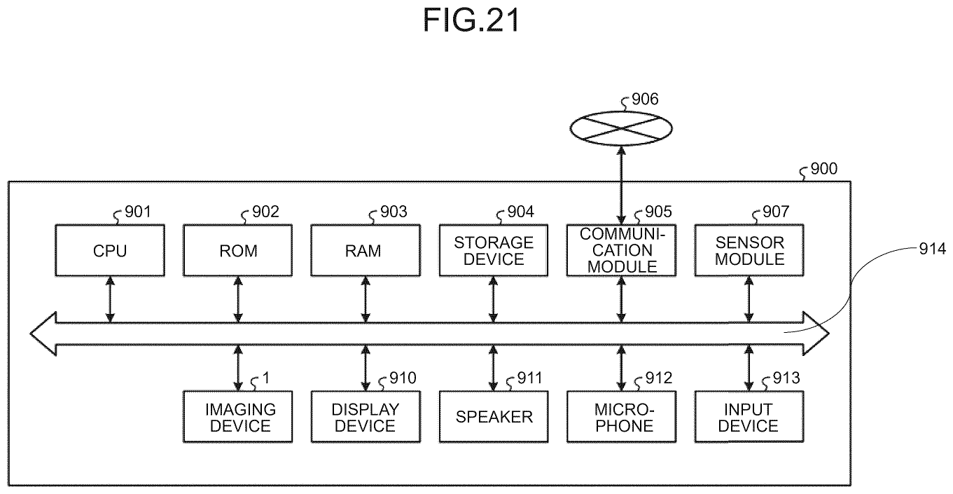

The technique according to the present disclosure (present technique) can be further applied to various products. For example, the technique according to the present disclosure may be applied to a smartphone or the like. Thus, a configuration example of a smartphone 900 as an electronic apparatus that applies the present technique will be described with reference to FIG. 21. FIG. 21 is a block diagram illustrating an example of a schematic functional configuration of the smartphone 900 to which the technique according to the present disclosure (the present technique) can be applied.

As illustrated in FIG. 21, the smartphone 900 includes a central processing unit (CPU) 901, a read only memory (ROM) 902, and a random access memory (RAM) 903. In addition, the smartphone 900 includes a storage device 904, a communication module 905, and a sensor module 907. Furthermore, the smartphone 900 includes the imaging device 1, a display device 910, a speaker 911, a microphone 912, an input device 913, and a bus 914. In addition, the smartphone 900 may include a processing circuit such as a digital signal processor (DSP) instead of or in addition to the CPU 901.

The CPU 901 functions as an arithmetic processing device and a control device, and controls the overall operation in the smartphone 900 or a part thereof according to various programs recorded in the ROM 902, the RAM 903, the storage device 904, or the like. The ROM 902 stores programs, operation parameters, and the like used by the CPU 901. The RAM 903 primarily stores programs used in the execution by the CPU 901, parameters that appropriately change in the execution, and the like. The CPU 901, the ROM 902, and the RAM 903 are connected to one another by the bus 914. In addition, the storage device 904 is a device for data storage configured as an example of a storage section of the smartphone 900. The storage device 904 includes, for example, a magnetic storage device such as a hard disk drive (HDD), a semiconductor storage device, an optical storage device, or the like. The storage device 904 stores programs and various data executed by the CPU 901, various data acquired from the outside, and the like.

The communication module 905 is a communication interface including, for example, a communication device for connection to a communication network 906. The communication module 905 can be, for example, a communication card for wired or wireless local area network (LAN), Bluetooth (registered trademark), wireless USB (WUSB), or the like. In addition, the communication module 905 may be a router for optical communication, a router for asymmetric digital subscriber line (ADSL), a modem for various types of communication, or the like. The communication module 905 transmits and receives a signal and the like to and from the Internet and other communication devices using a predetermined protocol such as Transmission Control Protocol (TCP)/Internet Protocol (IP). In addition, the communication network 906 connected to the communication module 905 is a network connected in a wired or wireless manner, and is, for example, the Internet, a home LAN, infrared communication, satellite communication, or the like.

The sensor module 907 includes, for example, various sensors such as a motion sensor (for example, an acceleration sensor, a gyro sensor, a geomagnetic sensor, or the like), a biological information sensor (for example, a pulse sensor, a blood pressure sensor, a fingerprint sensor, and the like.), or a position sensor (for example, a global navigation satellite system (GNSS) receiver or the like).

The imaging device 1 is provided on a surface of the smartphone 900, and can image an object or the like located on the back side or the front side of the smartphone 900. Specifically, the imaging device 1 can include an imaging element (not illustrated) such as a complementary MOS (CMOS) image sensor to which the technique according to the present disclosure (present technique) can be applied, and a signal processing circuit (not illustrated) that performs imaging signal processing on a signal subjected to photoelectrical conversion by the imaging element. Furthermore, the imaging device 1 can further include an optical system mechanism (not illustrated) including an imaging lens, a zoom lens, a focus lens, and the like, and a drive system mechanism (not illustrated) that controls an operation of the optical system mechanism. Then, the imaging element collects incident light from the object as an optical image, and the signal processing circuit photoelectrically converts the formed optical image in units of pixels, reads a signal of each pixel as an imaging signal, and performs image processing to acquire a captured image.

The display device 910 is provided on the surface of the smartphone 900, and can be, for example, a display device such as a liquid crystal display (LCD) or an organic electro luminescence (EL) display. The display device 910 can display an operation screen, the captured image acquired by the above-described imaging device 1, and the like.

The speaker 911 can output, for example, a call voice, a sound accompanying a video content displayed by the above-described display device 910, and the like to the user.

The microphone 912 can collect, for example, the call voice of the user, a voice including a command to activate a function of the smartphone 900, and a sound in a surrounding environment of the smartphone 900.

The input device 913 is a button, a keyboard, a touch panel, a mouse, or other devices operated by the user. The input device 913 includes an input control circuit that generates an input signal based on information input by the user and outputs the input signal to the CPU 901. By operating the input device 913, the user can input various data and give an instruction on a processing operation to the smartphone 900.

The configuration example of the smartphone 900 has been described above. Each of the above-described components may be constituted using a general-purpose member, or may be constituted by hardware specialized for the function of each component. Such a configuration can be appropriately changed according to the technical level at the time of implementation.

### <8.3 Application Example to a Mobile Body>

The technique according to the present disclosure (present technique) can be applied to various products. For example, the technique according to the present disclosure may be implemented as a device mounted on any type of mobile body such as an automobile, an electric vehicle, a hybrid electric vehicle, a motorcycle, a bicycle, a personal mobility, an airplane, a drone, a ship, and a robot.

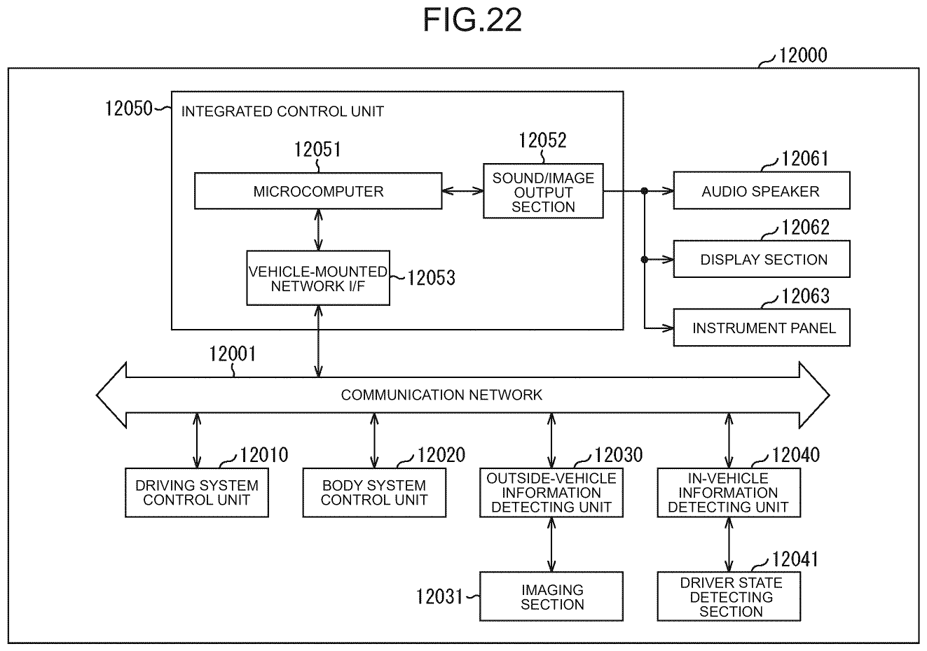

FIG. 22 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 22, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 22, an audio speaker 12061, a display section 12062, and an instrument panel 12063 are illustrated as the output device. The display section 12062 may, for example, include at least one of an on-board display and a head-up display.

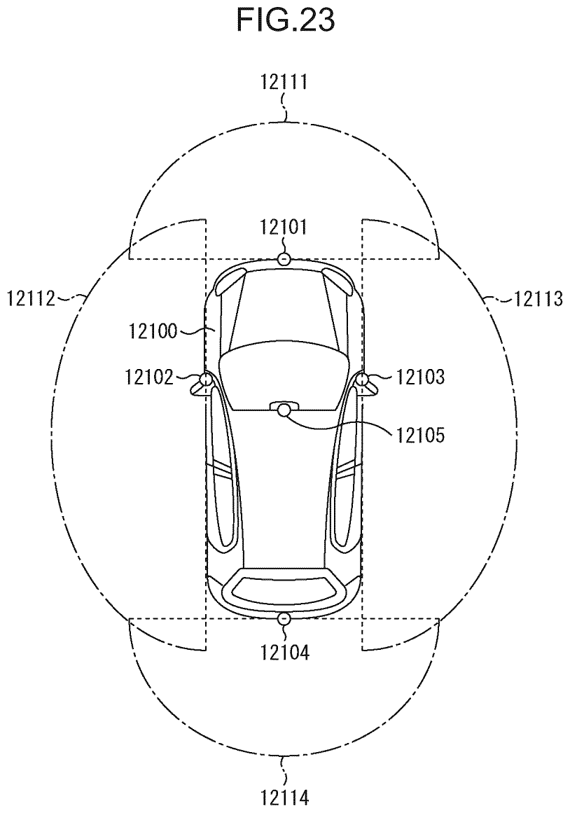

FIG. 23 is a diagram depicting an example of the installation position of the imaging section 12031.

In FIG. 23, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 23 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technique according to the present disclosure can be applied has been described above. The technique according to the present disclosure can be applied to the imaging section 12031 or the like among the configurations described above.

### 9. Supplement

Although the preferred embodiments of the present disclosure have been described in detail with reference to the accompanying drawings, the technical scope of the present disclosure is not limited to such examples. It is obvious that a person having ordinary knowledge in the technical field of the present disclosure can conceive various changes or modifications within the scope of the technical idea described in the claims, and it is naturally understood that these also belong to the technical scope of the present disclosure.

In addition, the effects described herein are merely illustrative or exemplary, and are not restrictive. That is, the technique according to the present disclosure can exhibit other effects obvious to those skilled in the art from the description herein together with or instead of the above effects.

The present technique may also have the following configurations:
(1) A light detection element comprising:
   a photoelectric conversion section that is provided in a semiconductor substrate and generates a charge corresponding to incident light;
   a first accumulation section that accumulates the charge generated by the photoelectric conversion section;
   an amplification transistor that generates an input signal corresponding to an amount of the charges accumulated in the first accumulation section;
   a second accumulation section to which a saturated charge is transferred from the photoelectric conversion section via the first accumulation section;
   a conversion efficiency switching transistor that transfers the saturated charge to the second accumulation section to switch a conversion efficiency;
   a reset transistor that resets the charge accumulated in the first accumulation section and the saturated charge accumulated in the second accumulation section; and
   a differential input circuit that compares the input signal generated by the amplification transistor with a reference signal and outputs a comparison result, wherein
   the second accumulation section includes
   a metal insulator metal (MIM) capacitor having a three-dimensional structure or a metal oxide semiconductor (MOS) capacitor.
(2) The light detection element according to (1), wherein
   the MIM capacitor has
   a stacked structure including a pair of metal layers sandwiching an insulating layer, and
   a cross section along a stacking direction of the stacked structure has a substantially rectangular wave shape.
(3) The light detection element according to (2), wherein one of the pair of metal layers is electrically connected to a power supply, a ground, or a well region of the semiconductor substrate.
(4) The light detection element according to (1), wherein
   the second accumulation section includes a plurality of the MIM capacitors.
(5) The light detection element according to (4), wherein
   each of the plurality of MIM capacitors has
   a stacked structure including a pair of metal layers sandwiching an insulating layer, and
   one of the pair of metal layers of each of the plurality of MIM capacitors is electrically connected to one destination selected from a power source, a ground, or a well region of the semiconductor substrate, the selected destination of one of the plurality of MIM capacitors being different from that of another of the plurality of MIM capacitors.
(6) The light detection element according to any one of (1) to (5), wherein the MIM capacitor is provided in a wiring layer stacked on the semiconductor substrate.
(7) The light detection element according to (1), wherein the MOS capacitor includes an oxide film provided on the semiconductor substrate and an electrode provided on the oxide film.
(8) The light detection element according to (7), wherein the electrode is electrically connected to a power supply, a ground, or a well region of the semiconductor substrate.
(9) The light detection element according to (1), wherein
   the second accumulation section includes a plurality of the MOS capacitors.
(10) The light detection element according to (9), wherein
   each of the plurality of MOS capacitors has
   an oxide film provided on the semiconductor substrate and an electrode provided on the oxide film, and
   the electrode of each of the plurality of MOS capacitors is electrically connected to one destination selected from a power source, a ground, or a well region of the semiconductor substrate, the selected destination of one of the plurality of MOS capacitors being different from that of another of the plurality of MOS capacitors.
(11) The light detection element according to any one of (1) to (10), wherein
   the photoelectric conversion section contains an impurity of a first conductivity type, and
   the light detection element further comprises:
   a pixel separation section that penetrates the semiconductor substrate in a film thickness direction of the semiconductor substrate and defines the photoelectric conversion section; and
   a diffusion region provided between the photoelectric conversion section and the pixel separation section and containing an impurity of a second conductivity type different from the first conductivity type.
(12) The light detection element according to (11), wherein the diffusion region contains the impurity of the second conductivity type diffused from an inner wall of a trench provided when the pixel separation section is formed.
(13) The light detection element according to (1), wherein one terminal of the second accumulation section is electrically connected to one or a plurality of connection pads for connection to a power supply or a ground via wiring.
(14) The light detection element according to any one of (1) to (13), further comprising:
   a positive feedback circuit connected to the differential input circuit; and
   a storage section connected to the positive feedback circuit.
(15) A light detection device including: a semiconductor substrate on which a plurality of light detection elements are provided; and another semiconductor substrate stacked on the semiconductor substrate, in which
   the light detection element includes:
   a photoelectric conversion section that generates a charge corresponding to incident light;
   a first accumulation section that accumulates the charge generated by the photoelectric conversion section;
   an amplification transistor that generates an input signal corresponding to an amount of the charges accumulated in the first accumulation section;
   a second accumulation section to which a saturated charge is transferred from the photoelectric conversion section via the first accumulation section;
   a conversion efficiency switching transistor that transfers the saturated charge to the second accumulation section to switch a conversion efficiency;
   a reset transistor that resets the charge accumulated in the first accumulation section and the saturated charge accumulated in the second accumulation section; and
   a differential input circuit that compares the input signal generated by the amplification transistor with a reference signal and outputs a comparison result, and
   the second accumulation section includes
   a metal insulator metal (MIM) capacitor having a three-dimensional structure or a metal oxide semiconductor (MOS) capacitor.
(16) The light detection device according to (15), in which one terminal of the second accumulation section is electrically connected to one or a plurality of connection pads provided on the other semiconductor substrate for connection to a power supply, a ground, or a well region via a through via penetrating a wiring layer between the semiconductor substrate and the other semiconductor substrate.
(17) An electronic apparatus on which a light detection device including a light detection element is mounted, wherein
   the light detection element includes:
   a photoelectric conversion section that is provided in a semiconductor substrate and generates a charge corresponding to incident light;
   a first accumulation section that accumulates the charge generated by the photoelectric conversion section;
   an amplification transistor that generates an input signal corresponding to an amount of the charges accumulated in the first accumulation section;
   a second accumulation section to which a saturated charge is transferred from the photoelectric conversion section via the first accumulation section;
   a conversion efficiency switching transistor that transfers the saturated charge to the second accumulation section to switch a conversion efficiency;
   a reset transistor that resets the charge accumulated in the first accumulation section and the saturated charge accumulated in the second accumulation section; and
   a differential input circuit that compares the input signal generated by the amplification transistor with a reference signal and outputs a comparison result, and
   the second accumulation section includes
   a metal insulator metal (MIM) capacitor having a three-dimensional structure or a metal oxide semiconductor (MOS) capacitor.

### REFERENCE SIGNS LIST

1 IMAGING DEVICE
11 SEMICONDUCTOR SUBSTRATE
21 PIXEL
22 PIXEL ARRAY SECTION
23 PIXEL DRIVE CIRCUIT
24 DAC
25 VERTICAL DRIVE CIRCUIT
26 SENSE AMPLIFICATION SECTION
27 OUTPUT SECTION
28 TIMING GENERATION CIRCUIT
41 PIXEL CIRCUIT
42 ADC
52 DATA STORAGE SECTION
61 COMPARATOR
62 POSITIVE FEEDBACK CIRCUIT
70a, 70b SUBSTRATE
101, 152, 304 PD
102, 153, 306t TRANSFER TRANSISTOR
103, 154 FD SECTION
151 DISCHARGE TRANSISTOR
155, 202, 306a AMPLIFICATION TRANSISTOR
156, 201, 306f CONVERSION EFFICIENCY SWITCHING TRANSISTOR
157 CAPACITOR
158, 204, 306r RESET TRANSISTOR
159, 160, 161, 162, 163, 165 TRANSISTOR
167 POWER SUPPLY LINE
170 NODE
203 SELECTION TRANSISTOR
205 VERTICAL SIGNAL LINE
300 SEMICONDUCTOR SUBSTRATE
302 REGION
306 PIXEL TRANSISTOR
308 DIFFUSION REGION
310, 312 SOLID-PHASE DIFFUSION LAYER
314 SILICON OXIDE FILM
316 POLYSILICON FILM
320 PIXEL SEPARATION SECTION
400 WIRING LAYER
402 INSULATING FILM
404, 404a, 404b, 404c, 404d WIRING
410, 806 THROUGH VIA
420, 420a, 420b THREE-DIMENSIONAL MIM CAPACITOR
422, 426 METAL LAYER
424 DIELECTRIC LAYER
428 CONTACT
430 MOS CAPACITOR
502 PLANARIZATION FILM
504 LIGHT SHIELDING FILM
506 ON-CHIP LENS
800, 800a, 800b PAD
802 WIRING NETWORK
804 POTENTIAL GENERATION MEANS
810 DRIVING MEANS

What is claimed is:

1. A light detection element, comprising:
a photoelectric conversion section that is provided in a semiconductor substrate and generates a charge corresponding to incident light;
a first accumulation section that accumulates the charge generated by the photoelectric conversion section;
an amplification transistor that generates an input signal corresponding to an amount of the charges accumulated in the first accumulation section;
a second accumulation section to which a saturated charge is transferred from the photoelectric conversion section via the first accumulation section;
a conversion efficiency switching transistor that transfers the saturated charge to the second accumulation section to switch a conversion efficiency;
a reset transistor that resets the charge accumulated in the first accumulation section and the saturated charge accumulated in the second accumulation section; and
a differential input circuit that compares the input signal generated by the amplification transistor with a reference signal and outputs a comparison result, wherein
the second accumulation section includes
a metal insulator metal (MIM) capacitor having a three-dimensional structure or a metal oxide semiconductor (MOS) capacitor.

2. The light detection element according to claim 1, wherein
the MIM capacitor has
a stacked structure including a pair of metal layers sandwiching an insulating layer, and
a cross section along a stacking direction of the stacked structure has a substantially rectangular wave shape.

3. The light detection element according to claim 2, wherein one of the pair of metal layers is electrically connected to a power supply, a ground, or a well region of the semiconductor substrate.

4. The light detection element according to claim 1, wherein
the second accumulation section includes a plurality of the MIM capacitors.

5. The light detection element according to claim 4, wherein
each of the plurality of MIM capacitors has
a stacked structure including a pair of metal layers sandwiching an insulating layer, and
one of the pair of metal layers of each of the plurality of MIM capacitors is electrically connected to one destination selected from a power source, a ground, or a well region of the semiconductor substrate, the selected destination of one of the plurality of MIM capacitors being different from that of another of the plurality of MIM capacitors.

6. The light detection element according to claim 1, wherein the MIM capacitor is provided in a wiring layer stacked on the semiconductor substrate.

7. The light detection element according to claim 1, wherein the MOS capacitor includes an oxide film provided on the semiconductor substrate and an electrode provided on the oxide film.

8. The light detection element according to claim 7, wherein the electrode is electrically connected to a power supply, a ground, or a well region of the semiconductor substrate.

9. The light detection element according to claim 1, wherein
the second accumulation section includes a plurality of the MOS capacitors.

10. The light detection element according to claim 9, wherein
each of the plurality of MOS capacitors has
an oxide film provided on the semiconductor substrate and an electrode provided on the oxide film, and
the electrode of each of the plurality of MOS capacitors is electrically connected to one destination selected from a power source, a ground, or a well region of the semiconductor substrate, the selected destination of one of the plurality of MOS capacitors being different from that of another of the plurality of MOS capacitors.

11. The light detection element according to claim 1, wherein
the photoelectric conversion section contains an impurity of a first conductivity type, and
the light detection element further comprises:
a pixel separation section that penetrates the semiconductor substrate in a film thickness direction of the semiconductor substrate and defines the photoelectric conversion section; and
a diffusion region provided between the photoelectric conversion section and the pixel separation section and containing an impurity of a second conductivity type different from the first conductivity type.

12. The light detection element according to claim 11, wherein the diffusion region contains the impurity of the second conductivity type diffused from an inner wall of a trench provided when the pixel separation section is formed.

13. The light detection element according to claim 1, wherein one terminal of the second accumulation section is electrically connected to one or a plurality of connection pads for connection to a power supply or a ground via wiring.

14. The light detection element according to claim 1, further comprising:
a positive feedback circuit connected to the differential input circuit; and
a storage section connected to the positive feedback circuit.

15. An electronic apparatus on which a light detection device including a light detection element is mounted, wherein
the light detection element includes:
a photoelectric conversion section that is provided in a semiconductor substrate and generates a charge corresponding to incident light;
a first accumulation section that accumulates the charge generated by the photoelectric conversion section;
an amplification transistor that generates an input signal corresponding to an amount of the charges accumulated in the first accumulation section;
a second accumulation section to which a saturated charge is transferred from the photoelectric conversion section via the first accumulation section;
a conversion efficiency switching transistor that transfers the saturated charge to the second accumulation section to switch a conversion efficiency;
a reset transistor that resets the charge accumulated in the first accumulation section and the saturated charge accumulated in the second accumulation section; and
a differential input circuit that compares the input signal generated by the amplification transistor with a reference signal and outputs a comparison result, and
the second accumulation section includes
a metal insulator metal (MIM) capacitor having a three-dimensional structure or a metal oxide semiconductor (MOS) capacitor.
